(19) United States
(12) Patent Application Publication
(10) Pub. No.: US 2025/0359390 A1
(43) Pub. Date: Nov. 20, 2025

(54) CELL STRING MANUFACTURING APPARATUS AND STRING SOLDERING MACHINE

(71) Applicant: SUZHOU MAXWELL TECHNOLOGIES CO., LTD., Suzhou (CN)

(72) Inventors: Kaile FANG, Suzhou (CN); Shangan WANG, Suzhou (CN); Yi TAO, Suzhou (CN)

(73) Assignee: SUZHOU MAXWELL TECHNOLOGIES CO., LTD., Suzhou (CN)

(21) Appl. No.: 18/985,122

(22) Filed: Dec. 18, 2024

(30) Foreign Application Priority Data
May 15, 2024 (CN) 202421051123.3

(51) Int. Cl. H10F 71/00

(52) U.S. Cl. CPC H10F 71/1375

(57) ABSTRACT

Provided are a cell string manufacturing apparatus and a string soldering machine with the same. The apparatus includes a first support, a first conveyor roller, a second conveyor roller, a first transition roller, a second transition roller, a first compression roller, and a first conveyor belt. Part of the first conveyor belt is wound around the first transition roller, the first compression roller, and the second transition roller to form a string cutting groove. A string cutting mechanism is disposed on the first support and includes a string cutter and a first driving component for driving the string cutter into or out of the string cutting groove. The speeds of a cell string before and after being cut are consistent. A conventional way to convey the cell string with two independent conveyor belts can be abandoned to avoid string blockage. The operational stability of the apparatus can be improved.

### CROSS-REFERENCE TO RELATED APPLICATIONS

This application claims priority to Chinese Patent Application No. 202421051123.3, filed on May 15, 2024, the contents of each of which are hereby incorporated by reference.

### TECHNICAL FIELD

The present disclosure relates to the technical field of solar cells, in particular to a cell string manufacturing apparatus and a string soldering machine.

### BACKGROUND OF THE INVENTION

Conventional cell strings are generally used to manufacture a cell module through a string connecting and conveying mechanism, a string cutting mechanism, and a string separating and conveying mechanism. The string connecting and conveying mechanism, the string cutting mechanism, and the string separating and conveying mechanism convey the cell strings with independent conveyor belts respectively. Due to the speed difference between different conveyor belts, when the conveying speed of the conveyor belt of the string cutting mechanism is higher than the speed of the string connecting and conveying mechanism, the cell strings are prone to blockage on the conveyor belt of the string cutting mechanism, resulting in low operational stability of a cell string manufacturing apparatus.

### SUMMARY

The present disclosure aims to solve at least one of the technical problems existing in the prior art. In view of this, the present disclosure proposes a cell string manufacturing apparatus. The operational stability of the cell string manufacturing apparatus can be improved.

The present disclosure further proposes a string soldering machine with the above cell string manufacturing apparatus.

A cell string manufacturing apparatus according to an embodiment of a first aspect of the present disclosure includes a first support, a first conveyor roller, a second conveyor roller, a first transition roller, a second transition roller, a first compression roller, and a first conveyor belt, where the first conveyor roller, the second conveyor roller, the first transition roller, and the second transition roller are all rotatably disposed on the first support, the first transition roller is located between the first conveyor roller and the second conveyor roller, the second transition roller is located between the first transition roller and the second conveyor roller, the first compression roller is disposed between the first transition roller and the second transition roller, and has an upper end lower than an upper end of the first transition roller, the first conveyor belt is wound around the first conveyor roller, the first transition roller, the first compression roller, the second transition roller, and the second conveyor roller, the first conveyor belt is configured to convey a cell string, part of the first conveyor belt is wound around the first transition roller, the first compression roller, and the second transition roller to form a string cutting groove, and a string cutting mechanism is disposed on the first support and includes a string cutter and a first driving component for driving the string cutter into or out of the string cutting groove.

A cell string manufacturing apparatus according to an embodiment of a first aspect of the present disclosure has at least the following beneficial effects:

A part of the first conveyor belt at a front end of the string cutting mechanism is configured to convey the cell string formed by soldering of a soldering mechanism, and a part of the first conveyor belt at a rear end of the string cutting mechanism is configured to convey the cell string cut by the string cutter. When a ribbon of the cell string is located above the string cutting groove, the first driving component drives the string cutter to move down to cut the cell string. Then, the first driving component drives the string cutter to move up to wait for cutting a next ribbon. The speeds of the cell string before and after being cut are consistent, a conventional way to convey the cell string with two independent conveyor belts can be abandoned to avoid the occurrence of string blockage, and the operational stability of the cell string manufacturing apparatus can be improved.

According to some embodiments of the present disclosure, the string cutting mechanism further includes a compression assembly, where the compression assembly includes a compression member and a second driving component for driving the compression member to push the cell string to abut against the first conveyor belt.

According to some embodiments of the present disclosure, the compression member is located above the first transition roller.

According to some embodiments of the present disclosure, an upper end of the first conveyor roller, the upper end of the first transition roller, an upper end of the second transition roller, and an upper end of the second conveyor roller are flush.

According to some embodiments of the present disclosure, a tension roller assembly is further included, where the tension roller assembly includes a first tension roller and a second tension roller that are spaced apart along a length direction of the first conveyor belt, and the first conveyor belt is wound around the first tension roller and the second tension roller.

According to some embodiments of the present disclosure, an adjustment assembly is disposed between the first tension roller and the first support, and is configured to adjust a distance between the first tension roller and the second tension roller.

According to some embodiments of the present disclosure, the adjustment assembly includes an adjustment member and an elastic member, the first support is provided with a waist-shaped hole, one end of a roller shaft of the first tension roller is movably accommodated in the waist-shaped hole, a sidewall of the waist-shaped hole is provided with a threaded hole, the adjustment member is disposed in the threaded hole in a penetrating manner and is in thread fit with the threaded hole, one end of the adjustment member abuts against one end of the roller shaft of the first tension roller, and the elastic member is configured to cause one end of the roller shaft of the first tension roller to abut against one end of the adjustment member.

According to some embodiments of the present disclosure, a second support, a second conveyor belt, a third conveyor roller, and a fourth conveyor roller are further included, where the third conveyor roller and the fourth conveyor roller are both rotatably disposed on the second support, the second conveyor belt is wound around the third conveyor roller and the fourth conveyor roller, and the second conveyor belt is configured to convey the cell string cut by the string cutter.

According to some embodiments of the present disclosure, an upper surface of the first conveyor belt is flush with an upper surface of the second conveyor belt.

A string soldering machine according to an embodiment of a second aspect of the present disclosure includes the cell string manufacturing apparatus according to the above embodiment.

A string soldering machine according to an embodiment of a second aspect of the present disclosure has at least the following beneficial effects:

A part of the first conveyor belt at a front end of the string cutting mechanism is configured to convey the cell string formed by soldering of a soldering mechanism, and a part of the first conveyor belt at a rear end of the string cutting mechanism is configured to convey the cell string cut by the string cutter. When a ribbon of the cell string is located above the string cutting groove, the first driving component drives the string cutter to move down to cut the cell string. Then, the first driving component drives the string cutter to move up to wait for cutting a next ribbon. The speeds of the cell string before and after being cut are consistent, a conventional way to convey the cell string with two independent conveyor belts can be abandoned to avoid the occurrence of string blockage, and the operational stability of the cell string manufacturing apparatus can be improved.

The additional aspects and advantages of the present disclosure will be partially given in the description below, and part of them will become apparent from the description below or will be learned from the practice of the present disclosure.

### BRIEF DESCRIPTION OF THE DRAWINGS

The above and/or additional aspects and advantages of the present disclosure will become apparent and easy to understand from the description of embodiments with reference to the following drawings, in which:

FIG. 1 is a schematic structural diagram of a cell string manufacturing apparatus according to an embodiment of the present disclosure;

FIG. 2 is a top view of a cell string manufacturing apparatus according to an embodiment of the present disclosure;

FIG. 3 is a sectional view of a line A-A in FIG. 2;

FIG. 4 is a partial enlarged view of a part B in FIG. 3;

FIG. 5 is a schematic structural diagram of a string cutter mechanism according to an embodiment of the present disclosure;

FIG. 6 is a top view of a string cutter mechanism according to an embodiment of the present disclosure;

FIG. 7 is a sectional view of a line C-C in FIG. 6;

FIG. 8 is a schematic assembly diagram of an adjustment assembly and a first tension roller according to an embodiment of the present disclosure; and

FIG. 9 is a front view of an adjustment assembly and a first tension roller according to an embodiment of the present disclosure.

Reference Signs are as Follows:
first support 100, waist-shaped hole 110, first conveyor roller 210, second conveyor roller 220, first transition roller 230, second transition roller 240, first compression roller 250, first tension roller 260, second tension roller 270, third driving component 280, first conveyor belt 300, string cutting groove 310, string cutter mechanism 400, first driving component 410, string cutter 420, second driving component 430, compression member 440, adjustment member 510, elastic member 520, second support 610, second conveyor belt 620, third conveyor roller 630, fourth conveyor roller 640, and fourth driving component 650.

### DETAILED DESCRIPTION OF THE INVENTION

Embodiments of the present disclosure are described in detail below. Examples of the embodiments are shown in the accompanying drawings, in which the same or similar reference numerals represent the same or similar elements or elements with the same or similar functions throughout. The embodiments described below with reference to the accompanying drawings are exemplary and only intended to explain the present disclosure, and cannot be construed as limitations to the present disclosure.

In the description of the present disclosure, it is to be understood that the description of orientations is involved, for example, the terms “up”, “down”, “front”, “back”, “left”, “right”, and the like denote orientations or positional relationships based on orientations or positional relationships shown in the accompanying drawings, merely for the convenience of describing the present disclosure and simplifying the description, rather than indicating or implying that the apparatus or element referred to must have a particular orientation or be constructed and operated in a particular orientation, and therefore cannot be understood as limitations to the present disclosure.

In the description of the present disclosure, “several” refers to one or more, “a plurality of” refers to two or more, “greater than”, “less than”, “exceed”, etc. are understood as excluding itself, and “above”, “below”, “within”, etc. are understood as including itself. If there is a description of the terms “first” and “second”, they are only used for distinguishing technical features and should not be understood as indicating or implying relative importance, implicitly indicating the number of technical features indicated, or implicitly indicating the order of technical features indicated.

In the description of the present disclosure, unless otherwise explicitly limited, the terms such as “dispose”, “mount”, and “connect” should be broadly understood. Those skilled in the art may reasonably determine specific meanings of the above terms in the present disclosure based on specific content of the technical solution.

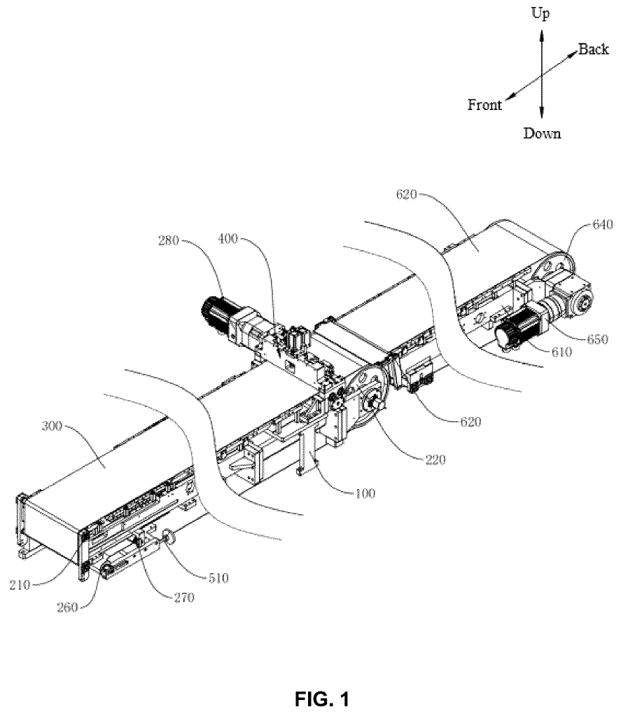

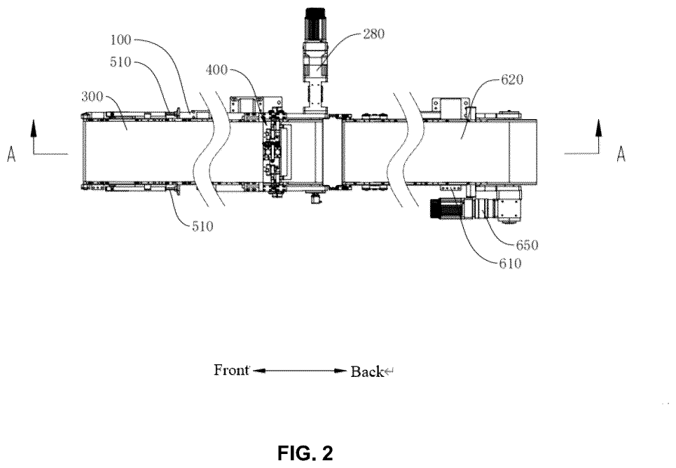

Referring to FIG. 1 to FIG. 4, a cell string manufacturing apparatus according to an embodiment of a first aspect of the present disclosure includes a first support 100, a first conveyor roller 210, a second conveyor roller 220, a first transition roller 230, a second transition roller 240, a first compression roller 250, and a first conveyor belt 300, where the first conveyor roller 210, the second conveyor roller 220, the first transition roller 230, and the second transition roller 240 are all rotatably disposed on the first support 100, the first transition roller 230 is located between the first conveyor roller 210 and the second conveyor roller 220, the second transition roller 240 is located between the first transition roller 230 and the second conveyor roller 220, the first compression roller 250 is disposed between the first transition roller 230 and the second transition roller 240, an upper end of the first compression roller 250 is lower than an upper end of the first transition roller 230, the first conveyor belt 300 is wound around the first conveyor roller 210, the first transition roller 230, the first compression roller 250, the second transition roller 240, and the second conveyor roller 220, the first conveyor belt 300 is configured to convey a cell string, part of the first conveyor belt 300 is wound around the first transition roller 230, the first compression roller 250, and the second transition roller 240 to form a string cutting groove 310, a string cutting mechanism is disposed on the first support 100 and includes a string cutter 420 and a first driving component 410, and the first driving component 410 is configured to drive the string cutter 420 into or out of the string cutting groove 310. In this way, the speeds of the cell string before and after being cut are consistent, a conventional way to convey the cell string with two independent conveyor belts can be abandoned to avoid the occurrence of string blockage, and the operational stability of the cell string manufacturing apparatus can be improved.

Specifically, a part of the first conveyor belt 300 at a front end of the string cutting mechanism is configured to convey the cell string formed by soldering of a soldering mechanism, and a part of the first conveyor belt 300 at a rear end of the string cutting mechanism is configured to convey the cell string cut by the string cutter 420. When a ribbon of the cell string is located above the string cutting groove 310, the first driving component 410 drives the string cutter 420 to move down to cut the cell string. Then, the first driving component 410 drives the string cutter 420 to move up to wait for cutting a next ribbon. The speeds of the cell string before and after being cut are consistent, a conventional way to convey the cell string with two independent conveyor belts can be abandoned to avoid the occurrence of string blockage, and the operational stability of the cell string manufacturing apparatus can be improved.

It is to be noted that a roller shaft of the second conveyor roller 220 is connected to a third driving component 280. The third driving component 280 can actively drive the second conveyor roller 220 to rotate, so as to move the first conveyor belt 300, which is not described in detail herein.

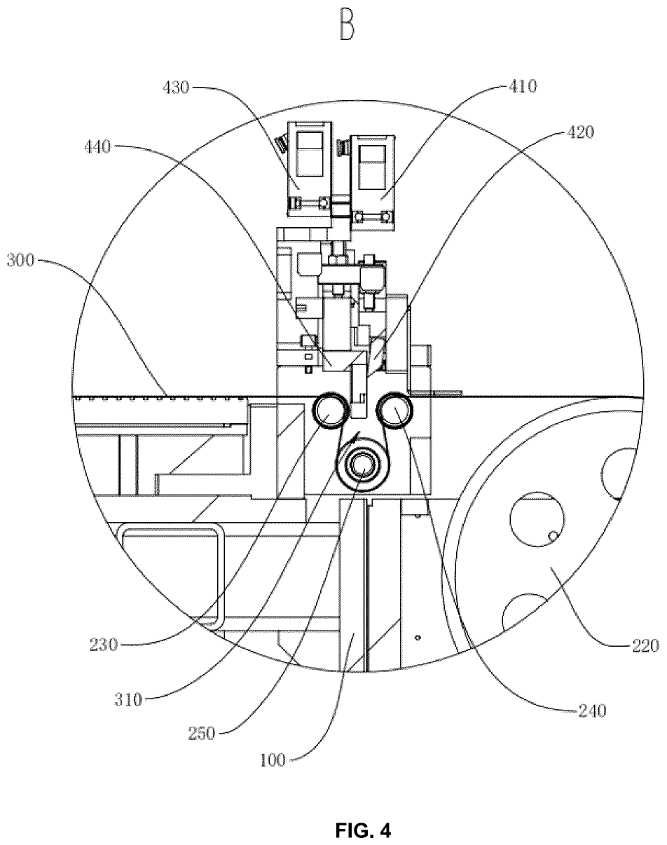

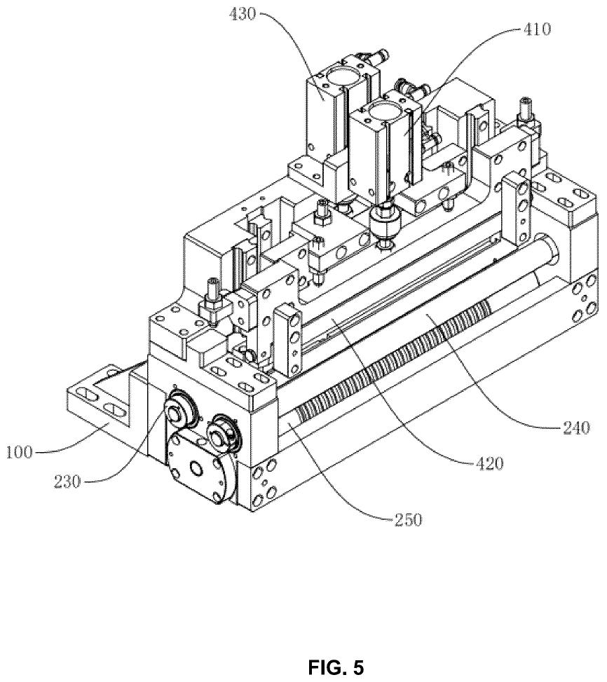

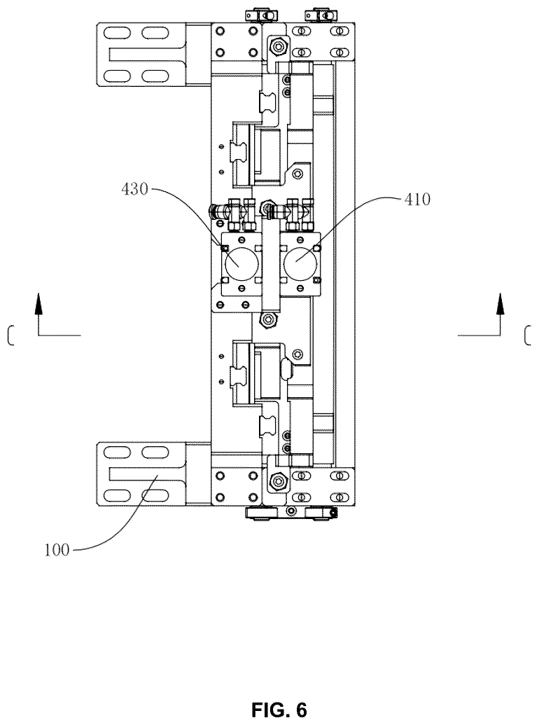

Referring to FIG. 4 to FIG. 7, in some embodiments of the present disclosure, the string cutting mechanism further includes a compression assembly, where the compression assembly includes a compression member 440 and a second driving component 430, and the second driving component 430 is configured to drive the compression member 440 to push the cell string to abut against the first conveyor belt 300. The deviation of the cell string can be reduced to improve the cutting stability of the string cutter 420, thereby improving the consistency in a cutting position of the ribbon.

Specifically, the second driving component 430 is mounted on the first support 100; the compression member 440 is disposed on the first support 100 and is movable along an up-down direction, and the compression member 440 is located above the first conveyor belt 300; and an output end of the second driving component 430 is connected to the compression member 440, so as to drive the compression member 440 to move along the up-down direction. Before the string cutter 420 cuts the ribbon, first, the second driving component 430 drives the compression member 440 to move down, and the compression member 440 pushes the cell string to abut against the first conveyor belt 300, so as to fix the ribbon; and then, the first driving component 410 drives the string cutter 420 to move down, so as to cut the ribbon. The deviation of the cell string can be reduced to improve the cutting stability of the string cutter 420, thereby improving the consistency in a cutting position of the ribbon.

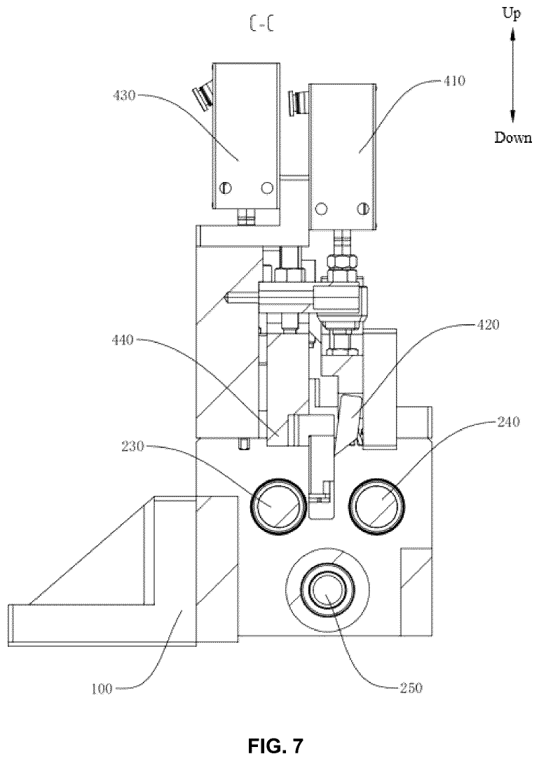

Referring to FIG. 7, in some embodiments of the present disclosure, the compression member 440 is located above the first transition roller 230. The deformation of the first conveyor belt 300 can be reduced, thereby prolonging the service life of the first conveyor belt 300.

Specifically, when the second driving component 430 drives the compression member 440 to push the cell string to abut against the first conveyor belt 300, a compressive force of the compression member 440 is transmitted to the first transition roller 230 through the first conveyor belt 300. The first transition roller 230 can bear the compressive force and reduce the deformation of the first conveyor belt 300, thereby prolonging the service life of the first conveyor belt 300.

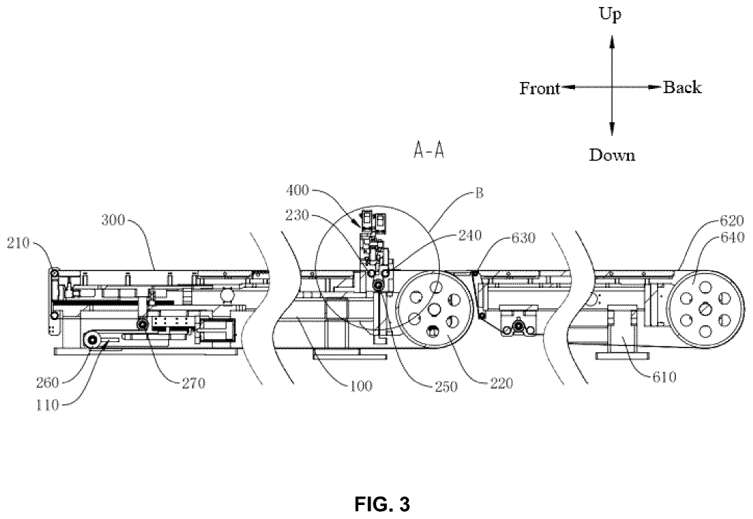

Referring to FIG. 3, in some embodiments of the present disclosure, an upper end of the first conveyor roller 210, the upper end of the first transition roller 230, an upper end of the second transition roller 240, and an upper end of the second conveyor roller 220 are flush, so that the first conveyor belt 300 has an upper surface parallel to a horizontal plane and can smoothly convey the cell string.

Referring to FIG. 3, in some embodiments of the present disclosure, a tension roller assembly is further included, where the tension roller assembly includes a first tension roller 260 and a second tension roller 270, the first tension roller 260 and the second tension roller 270 are spaced apart along a length direction of the first conveyor belt 300, and the first conveyor belt 300 is wound around the first tension roller 260 and the second tension roller 270, so that the first conveyor belt 300 is in a tight state and can stably convey the cell string.

Specifically, the first conveyor belt 300 is sequentially wound around the first conveyor roller 210, the first transition roller 230, the first compression roller 250, the second transition roller 240, the second conveyor roller 220, the second tension roller 270, and the first tension roller 260, so that the first conveyor belt 300 is in a tight state and can stably convey the cell string.

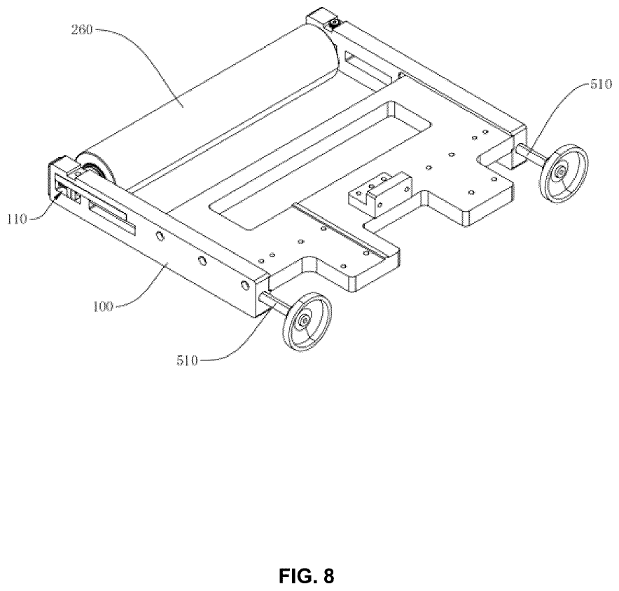

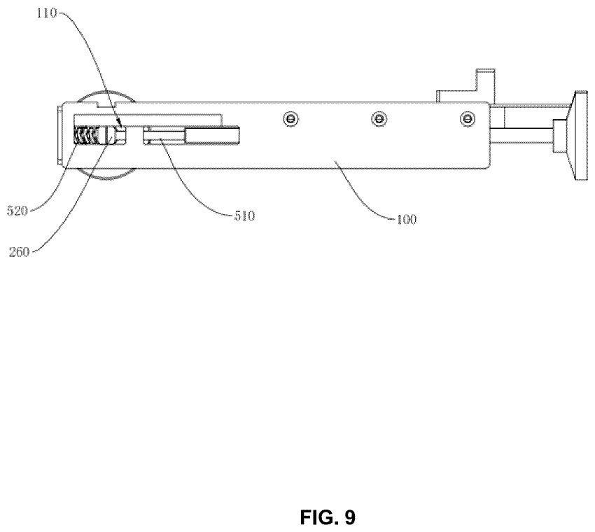

Referring to FIG. 3, FIG. 8, and FIG. 9, in some embodiments of the present disclosure, an adjustment assembly is disposed between the first tension roller 260 and the first support 100, and is configured to adjust a distance between the first tension roller 260 and the second tension roller 270. The tightness of the first conveyor belt 300 can be adjusted to prolong the service life of the first conveyor belt 300.

Specifically, the first conveyor belt 300 easily becomes loose after being used for a period of time. An operator can increase the distance between the first tension roller 260 and the second tension roller 270 by the adjustment assembly to keep the first conveyor belt 300 in a tight state, thereby prolonging the service life of the first conveyor belt 300.

Referring to FIG. 3, FIG. 8, and FIG. 9, in some embodiments of the present disclosure, the adjustment assembly includes an adjustment member 510 and an elastic member 520, the first support 100 is provided with a waist-shaped hole 110, one end of a roller shaft of the first tension roller 260 is movably accommodated in the waist-shaped hole 110, a sidewall of the waist-shaped hole 110 is provided with a threaded hole, the adjustment member 510 is disposed in the threaded hole in a penetrating manner and is in thread fit with the threaded hole, one end of the adjustment member 510 abuts against one end of the roller shaft of the first tension roller 260, and the elastic member 520 is configured to cause one end of the roller shaft of the first tension roller 260 to abut against one end of the adjustment member 510. The tightness of the first conveyor belt 300 can be adjusted to prolong the service life of the first conveyor belt 300.

Specifically, the elastic member 520 is a component that can undergo axial elastic deformation, such as a compression spring or rubber, one end of the elastic member 520 abuts against one side of the waist-shaped hole in a length direction of the waist-shaped hole 110, and the other end of the elastic member abuts against one side of the roller shaft of the first tension roller 260 away from the adjustment member 510. When the adjustment member 510 pushes the first tension roller 260 to move along a direction away from the second tension roller 270, the elastic member 520 is compressed. When the adjustment member 510 releases the first tension roller 260, the elastic member 520 pushes the first tension roller 260 to move along a direction close to the second tension roller 270, so that the distance between the first tension roller 260 and the second tension roller 270 increases or decreases. The tightness of the first conveyor belt 300 can be adjusted to prolong the service life of the first conveyor belt 300.

It is to be noted that the adjustment member 510 may also be in threaded connection with one end of the roller shaft of the first tension roller 260 and can also adjust the distance between the first tension roller 260 and the second tension roller 270, which is not described in detail herein.

Certainly, in some specific embodiments, the adjustment member 510 may also be connected to a driving motor, and the driving motor can drive the adjustment member 510 to rotate, so as to automatically adjust the distance between the first tension roller 260 and the second tension roller 270, which is not described in detail herein.

Referring to FIG. 3, in some embodiments of the present disclosure, a second support 610, a second conveyor belt 620, a third conveyor roller 630, and a fourth conveyor roller 640 are further included, where the third conveyor roller 630 and the fourth conveyor roller 640 are both rotatably disposed on the second support 610, the second conveyor belt 620 is wound around the third conveyor roller 630 and the fourth conveyor roller 640, and the second conveyor belt 620 is configured to convey the cell string cut by the string cutter 420. The second conveyor belt 620 can convey the cell string cut by the string cutter 420 in a timely manner to avoid blockage of the cell string on the first conveyor belt 300, thereby improving the operational stability of the cell string manufacturing apparatus.

It is to be noted that a roller shaft of the fourth conveyor roller 640 is connected to a fourth driving component 650. The fourth driving component 650 can actively drive the fourth conveyor roller 640 to rotate, so as to move the second conveyor belt 620, which is not described in detail herein.

It can be understood that the second support 610 is further provided with a third tension roller and a second compression roller, and the second conveyor belt 620 is wound around the third conveyor roller 630, the fourth conveyor roller 640, the third tension roller, and the second compression roller to keep the second conveyor belt 620 in a tight state, which is not described in detail herein.

It is to be pointed out that an upper surface of the first conveyor belt 300 is flush with an upper surface of the second conveyor belt 620, so that the cell string manufacturing apparatus can smoothly convey the cell string, which is not described in detail herein.

A string soldering machine according to an embodiment of a second aspect of the present disclosure includes the cell string manufacturing apparatus according to the embodiment of the first aspect of the present disclosure. The speeds of the cell string before and after being cut are consistent, a conventional way to convey the cell string with two independent conveyor belts can be abandoned to avoid the occurrence of string blockage, and the yield of the cell string can be improved.

Specifically, a part of the first conveyor belt 300 at a front end of the string cutting mechanism is configured to convey the cell string formed by soldering of a soldering mechanism, and a part of the first conveyor belt 300 at a rear end of the string cutting mechanism is configured to convey the cell string cut by the string cutter 420. When a ribbon of the cell string is located above the string cutting groove 310, the first driving component 410 drives the string cutter 420 to move down to cut the cell string. Then, the first driving component 410 drives the string cutter 420 to move up to wait for cutting a next ribbon. The speeds of the cell string before and after being cut are consistent, a conventional way to convey the cell string with two independent conveyor belts can be abandoned to avoid the occurrence of string blockage, and the operational stability of the cell string manufacturing apparatus can be improved.

It can be expected that the various driving components above may be cylinders, combinations of motors and ball screws, or other conventional driving parts such as hydraulic cylinders. Specific embodiments may be correspondingly adjusted based on actual requirements, which is not limited herein.

The technical features of the above embodiments may be combined arbitrarily. For simplicity of description, all possible combinations of the technical features in the above embodiments are not described. However, the combinations of these technical features should all be considered to be within the scope of this specification as long as there is no contradiction between them.

This embodiment has been described in detail above with reference to the accompanying drawings, but the present disclosure is not limited to the above embodiments. Various changes may also be made within the scope of knowledge of those of ordinary skill in the art without departing from the purpose.

What is claimed is:

1. A cell string manufacturing apparatus, comprising:
a first support;
a first conveyor roller and a second conveyor roller that are both rotatably disposed on the first support;
a first transition roller and a second transition roller that are both rotatably disposed on the first support, wherein the first transition roller is located between the first conveyor roller and the second conveyor roller, and the second transition roller is located between the first transition roller and the second conveyor roller;
a first compression roller disposed between the first transition roller and the second transition roller, and having an upper end lower than an upper end of the first transition roller;
a first conveyor belt wound around the first conveyor roller, the first transition roller, the first compression roller, the second transition roller, and the second conveyor roller, wherein the first conveyor belt is configured to convey a cell string, and part of the first conveyor belt is wound around the first transition roller, the first compression roller, and the second transition roller to form a string cutting groove; and
a string cutting mechanism disposed on the first support and comprising a string cutter and a first driving component for driving the string cutter into or out of the string cutting groove.

2. The cell string manufacturing apparatus according to claim 1, wherein the string cutting mechanism further comprises a compression assembly, and the compression assembly comprises a compression member and a second driving component for driving the compression member to push the cell string to abut against the first conveyor belt.

3. The cell string manufacturing apparatus according to claim 2, wherein the compression member is located above the first transition roller.

4. The cell string manufacturing apparatus according to claim 1, wherein an upper end of the first conveyor roller, the upper end of the first transition roller, an upper end of the second transition roller, and an upper end of the second conveyor roller are flush.

5. The cell string manufacturing apparatus according to claim 1, further comprising a tension roller assembly, wherein the tension roller assembly comprises a first tension roller and a second tension roller that are spaced apart along a length direction of the first conveyor belt, and the first conveyor belt is wound around the first tension roller and the second tension roller.

6. The cell string manufacturing apparatus according to claim 5, wherein an adjustment assembly is disposed between the first tension roller and the first support, and is configured to adjust a distance between the first tension roller and the second tension roller.

7. The cell string manufacturing apparatus according to claim 6, wherein the adjustment assembly comprises an adjustment member and an elastic member, the first support is provided with a waist-shaped hole, one end of a roller shaft of the first tension roller is movably accommodated in the waist-shaped hole, a sidewall of the waist-shaped hole is provided with a threaded hole, the adjustment member is disposed in the threaded hole in a penetrating manner and is in thread fit with the threaded hole, one end of the adjustment member abuts against one end of the roller shaft of the first tension roller, and the elastic member is configured to cause one end of the roller shaft of the first tension roller to abut against one end of the adjustment member.

8. The cell string manufacturing apparatus according to claim 1, further comprising a second support, a second conveyor belt, a third conveyor roller, and a fourth conveyor roller, wherein the third conveyor roller and the fourth conveyor roller are both rotatably disposed on the second support, the second conveyor belt is wound around the third conveyor roller and the fourth conveyor roller, and the second conveyor belt is configured to convey the cell string cut by the string cutter.

9. The cell string manufacturing apparatus according to claim 8, wherein an upper surface of the first conveyor belt is flush with an upper surface of the second conveyor belt.

10. A string soldering machine, comprising the cell string manufacturing apparatus according to claim 1.
